(19) United States
(12) Patent Application Publication
(10) Pub. No.: US 2019/0116680 A1
(43) Pub. Date: Apr. 18, 2019

(54) STABILISING BLOCK

(71) Applicant: TOPLEFT CONCEPTS LTD., Newcastle upon Tyne (GB)

(72) Inventor: Kai NG, Newcastle upon Tyne (GB)

(21) Appl. No.: 16/158,283

(22) Filed: Oct. 11, 2018

(30) Foreign Application Priority Data
Oct. 12, 2017 (GB) 1716748.7

(51) Int. Cl. H05K 5/02; F16M 13/02

(52) U.S. Cl. CPC H05K 5/0204; H05K 7/14; F16M 13/02

(57) ABSTRACT

A stabilising block for holding an electronic tablet in place on a surface. The stabilising block comprises a fixing layer for fixing the block to the surface, a first stabilising part, and a second stabilising part. The first stabilising part provides a tablet engaging surface and said second stabilising part projects above said first stabilising part forming a tablet stop.

### CROSS-REFERENCE TO RELATED APPLICATIONS

This application is a non-provisional U.S. application which claims priority to British Application No. 1716748.7, filed 12 Oct. 2017. The disclosure of the priority application is incorporated in its entirety herein by reference.

### TECHNICAL FIELD

The present invention relates to stabilising blocks for holding in place electronic devices, in particular electronic tablet devices.

### BACKGROUND

Electronic tablets are well known and widely used consumer devices. Electronic tablets are typically equipped with a touchscreen which a user interacts with by performing particular types of touch-based control input including, tapping, swiping, pinching, drawing and so on. By performing these actions, lateral (sideways) forces are exerted on the tablet, analogous to those produced when a croupier draws a playing card from a card dealing shoe. Accordingly, when interacting with a touchscreen tablet, even when rested on a table for example, it is incumbent on the user to stop the tablet moving or sliding around. Normally the user is forced to achieve this manually by using a nonoperating hand and fingers to grip the tablet or to restore its position. This limits the ability of a user to interact with a tablet with both hands, for example for two-hand typing or operating additional computer input devices. This is a significant drawback as, increasingly, the computing performance of tablets can compete with traditionally larger devices which do not require a user to physically stabilise them in use, such as desk mounted personal computers and laptops.

Most electronic tablets and tablet covers are designed as lightweight, sleek, easy-to-hold personal instruments. Such design constraints typically do not optimise tablets for use when rested on a surface. Examples of electronic tablets include Apple Inc's “iPad” series of tablets and Samsung Electronics co. Ltd.'s “Galaxy Tab” series of tablets.

### SUMMARY OF INVENTION

In accordance with a first aspect of the invention, there is provided a stabilising block for holding an electronic tablet in place on a surface. The stabilising block comprises a fixing layer for fixing the block to the surface, a first stabilising part, and a second stabilising part. The first stabilising part provides a tablet engaging surface and said second stabilising part projects above said first stabilising part forming a tablet stop.

Optionally, the first stabilising part is substantially planar.

Optionally, the fixing layer is an adhesive layer.

Optionally, the adhesive layer is a pressure sensitive adhesive layer.

Optionally, the pressure sensitive adhesive layer is a pressure sensitive medium-tack adhesive cloth.

Optionally, the adhesive layer is a semi-permanent, reusable adhesive layer.

Optionally, the adhesive layer is disposed on a base of the stabilising block adjacent a flexible core layer.

Optionally, the flexible core layer comprises a plastic sheet.

Optionally, the second stabilising part comprises high friction cell foam.

Optionally, the first stabilising part comprises high friction cell foam.

Optionally, the block is formed by adhering together the first stabilising part and the second stabilising part.

Optionally, the first stabilising part and second stabilising part are formed from a single shaped piece.

Optionally, the first stabilising part and second stabilising part are formed by carving or cast moulding.

Optionally, a cross-section of the second stabilising part is substantially L-shaped.

Optionally, a peripheral edge of the first stabilising part comprises at least two rounded corners.

In accordance with a second aspect of the invention, there is provided a kit of parts comprising a plurality of stabilising blocks according to the first aspect.

Optionally, the kit of parts comprises at least four stabilising blocks.

In accordance with aspects of the invention, a stabilising block is provided that holds a tablet in place on a surface when the tablet is in use. The stabilising block is fixed on the surface by a fixing layer, typically provided by an adhesive layer.

Advantageously, the block includes two stabilising parts which each perform a specific stabilising function. Each stabilising function addresses a different stability issue associated with the use of electronic tablets when placed on a moveable surface.

Moreover, the arrangement of the components of blocks in accordance with embodiments of the invention is such that use of a tablet stabilised by one or more blocks reinforces the adhesion with which the block is secured to the surface.

More specifically, in accordance with aspects of the invention, a stabilising block includes a first stabilising part which provides a tablet engaging surface. The tablet engaging surface, which may typically be substantially planar, resists lateral movement of the tablet caused by a user performing manual tablet-type control inputs (e.g. tapping, swiping, pinching, drawing and so on). The stabilising block includes a second stabilising part which provides a tablet stop that further resists the lateral movement of the tablet due to control inputs but also stops movement of the tablet due to tipping of the surface on which the tablet is placed. Such tipping may arise due to the tablet being placed on a moveable surface such as a lapboard.

In accordance with aspects of the invention, the tablet stop, in use, projects above the tablet engaging surface. By virtue of this configuration, the weight of the tablet, and any force component arising from user control input that acts down through the block to the surface typically reinforces the adhesion of the fixing layer to the surface.

The advantage of this configuration can be readily appreciated by considering a stabilising block of a simpler construction, i.e. one in which a simple tablet stop (e.g. a rectangular block) is adhered directly to the surface. Without a tablet engaging surface, such a simple stop would have less contact area with the surface therefore providing an inferior adhesion to the surface. Moreover, as the junction between the surface and the stabilising block would be directly at the edge of the tablet stop itself, the block would be liable to be prised and eventually “roll over” during use due to gradual accumulations of micro breakages in the adhesion caused by vibrations and lateral/tangential pressures that originate from user interactions with the tablet's touchscreen.

Further benefits of certain embodiments of the invention include low manufacturing cost, the fact that one or more blocks can be used for different size tablets and different types of tablet covers, and the fact that blocks in accordance with certain embodiments of the invention are effective for most types of lapboards and table-top surfaces.

Various further features and aspects of the invention are defined in the claims.

### BRIEF DESCRIPTION OF THE DRAWINGS

Embodiments of the present invention will now be described by way of example only with reference to the accompanying drawings where like parts are provided with corresponding reference numerals and in which:

FIG. 1 provides a simplified schematic diagram of a tablet stabilising block in accordance with certain examples of the invention;

FIG. 2 provides a simplified schematic diagram providing a cross-sectional view of a stabilising block in accordance with certain examples of the invention;

FIG. 3 provides a schematic diagram of an edge portion of a tablet positioned for maximal contact with a stabilising block in accordance with certain examples of the invention;

FIG. 4 provides a schematic diagram of a configuration of four stabilising blocks stabilising a tablet on a surface in accordance with certain examples of the invention;

FIG. 5 provides a schematic diagram of an edge portion of a tablet positioned for contact with a stabilising block in accordance with certain examples of the invention and in which the tablet is tilted by having one edge elevated;

FIG. 6 provides a schematic diagram of a configuration of two stabilising blocks stabilising a tablet on a surface in accordance with certain examples of the invention;

FIG. 7 provides a schematic diagram of a configuration of four stabilising blocks stabilising a tablet on a surface in accordance with certain examples of the invention in which in which the tablet is tilted by having one edge elevated, and

FIG. 8 provides a schematic diagram of a stabilising block in accordance with an embodiment of the invention.

### DETAILED DESCRIPTION

In accordance with certain embodiments of the invention, a stabilising block is provided that can be used individually or in multiples to stop a tablet sliding on a surface such as the surface of a lapboard, writing chair or any table furniture where the surface does not remain horizontally flat and free from motion throughout duration of use.

By applying one or more stabilising blocks in accordance with embodiments of the invention, unwanted movements are arrested without the user committing one hand to hold or balance the tablet. A user can thereby more productively perform two-hand typing and operate peripheral devices that may be connected to the tablet such as a computer mouse or pointing device (e.g. a stylus).

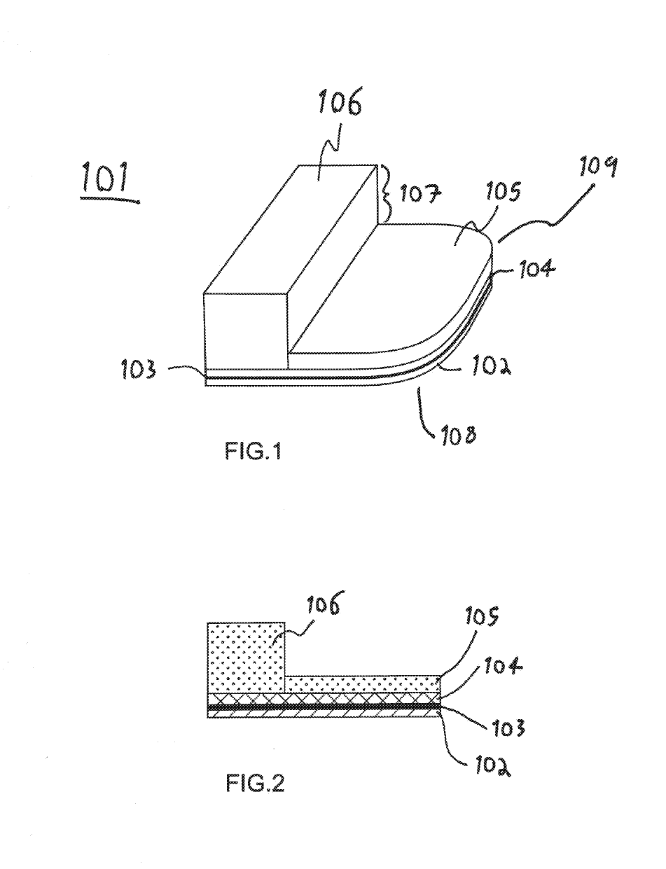

FIG. 1 provides a simplified schematic diagram of a stabilising block 101 in accordance with certain examples of the invention.

At the base of the block 101 there is a fixing layer typically provided by an adhesive layer 102 comprising, for example, a non-permanent pressure sensitive medium-tack adhesive cloth. In certain embodiments, the adhesive layer 102 is a double-sided medium tack adhesive cloth, that is the adhesive cloth has adhesive on both its sides.

Typically, the adhesive layer is approximately 0.35 mm thick.

Such non-permanent pressure sensitive adhesive cloths are well known in the art and after use can be peeled from a surface to which they have been applied without leaving any residue. Such adhesive layers are also reusable, that is, having been applied to a surface and then peeled, can be applied to a surface again.

Adjacent the adhesive layer 102 is a second, intermediate, adhesive layer 103. The intermediate adhesive layer 103 is typically provided by a high-tack double-sided adhesive tape. The purpose of the intermediate adhesive layer 103 is to ensure that when the stabilising block is removed from a surface, the adhesive layer 102 does not become distorted, or partially, or completely separated from the rest of the block. This is achieved because the adhesion of the adhesive layer 102 with the intermediate adhesive layer 103 is greater (due to the intermediate layer's high-tack adhesive) than the adhesion of the adhesive layer 102 with the surface which is adhered to the surface by the lower tack of the adhesive layer.

In certain embodiments, rather than the adhesive layer 102 on the base of the block and the intermediate adhesive layer 103, a single adhesive layer is provided. This single adhesive layer has a medium-tack adhesive on the surface-facing side for adhering the block to a surface, and a “stronger”, high-tack surface for adhering the single adhesive layer to the rest of the block.

Returning to FIG. 1, adjacent the intermediate adhesive layer 103 is a flexible core layer 104.

Typically, the flexible core layer 104 provides a thin stable base core that is flexible so that the stabilising block can be peeled with greater ease when separating it from the surface to which it has been adhered. In certain embodiments, the flexible core layer 104 is provided by a plastic sheet. The flexible core layer is chosen so that it is not so thin that it can become creased but not so thick that it becomes substantially rigid. Typically, the flexible core layer 104 is made from flexible plastic of thickness approximately 0.5 mm.

Adjacent the flexible core layer 104 is a first tablet stabilising part 105 comprising a first shaped block and a second tablet stabilising part 106 comprising a second shaped block. As can be seen from FIG. 1, the block forming the second tablet stabilising part 106 projects, in use, above the block forming the first tablet stabilising part. The shaped block forming the first tablet stabilising part is substantially planar. The shaped block forming the second tablet stabilising part is substantially a rectangular block with a square cross-section.

The block forming the first tablet stabilising part 105 provides a tablet engaging surface, which when in use, resists lateral movement of a tablet caused by forces generated by user generated tablet control movements (e.g. swiping and tapping a touch screen of the tablet). By projecting above the block forming the first tablet stabilising part 105, the block forming the second tablet stabilising part forms a tablet stop 107. As will be described in more detail below, this tablet stop inhibits movement of the tablet due to a surface on which it is rested being tilted.

In certain embodiments, the thickness of the first tablet stabilising part 105 is between approximately 1 and 2 mm. This thickness ensures a requisite level of rigidity/resilience for withstanding contact and movement of a tablet but minimises a drop between the tablet engaging surface and the surface to which the block is adhered.

In certain embodiments, the thickness of the second tablet stabilising part 106 is approximately 10 mm. In certain embodiments, the second tablet stabilising part 106 may be thicker, for example 20 mm.

Advantageously, in certain embodiments, the block from which the second tablet stabilising part 106 is formed comprises firm-grade high-friction cell foam (such as neoprene) or rubber. Such materials are high friction therefore engage well with material forming the outer surface of a tablet (e.g. plastic and aluminium) but are unlikely to damage or mark a tablet. Such materials (e.g. firm-grade high-friction cell foam or rubber) are also comparatively firm so that the second tablet stabilising part 106 resists deformation due to forces exerted on it by the tablet edge due to tipping of the surface and due to forces arising from user control inputs to the tablet, such as swiping and pinching actions.

In certain embodiments, alternative material can be used for the second tablet stabilising part including one of cork, silicone or injection-moldable thermoplastic elastomer (TPE).

In certain embodiments, the first tablet stabilising part 105 is also made from high friction firm-grade cell foam. However, as the first tablet stabilising part 105 is thin relative to the second tablet stabilising part, and, in use, sandwiched between the tablet and the surface to which the block is adhered, resisting deformation is of less importance, therefore the first tablet stabilising part 105 can be made, for example, from general purpose, or lighter grade, sheet high-friction foam, or a suitable fabric.

For ease of manufacture, advantageously, in certain embodiments, a cross-section of the block forming the second tablet stabilising part 106 is square.

Typically, the component parts of the stabilising block depicted in FIG. 1 are bonded together using strong adhesives or permanent adhesive tapes suitable for the materials in question.

As shown in FIG. 1, in certain embodiments, the first and second tablet stabilising parts are formed from separate parts (e.g. two different blocks of high-friction cell foam bonded by adhesive). In other embodiments, the first and second tablet stabilising parts may be formed by a single shaped block (e.g. a single block of high-friction cell foam with an L-shaped cross-section). Such a shaped block may be carved from one piece of material, cast moulded as one piece, or cut from a long strip exhibiting the requisite (e.g. L-shaped) profile.

In certain embodiments, as depicted in FIG. 1, a peripheral edge of the first tablet stabilising part 105 comprises two rounded corners 108, 109. Advantageously, such a configuration reduces the likelihood of unintended peeling of the block 101 as would be the case if the corners were not rounded, e.g. formed as a 90-degree corner.

FIG. 2 provides a schematic diagram depicting a cross-sectional view of a stabilising block in accordance with certain embodiments of the invention, and corresponding to the stabilising block depicted in FIG. 1.

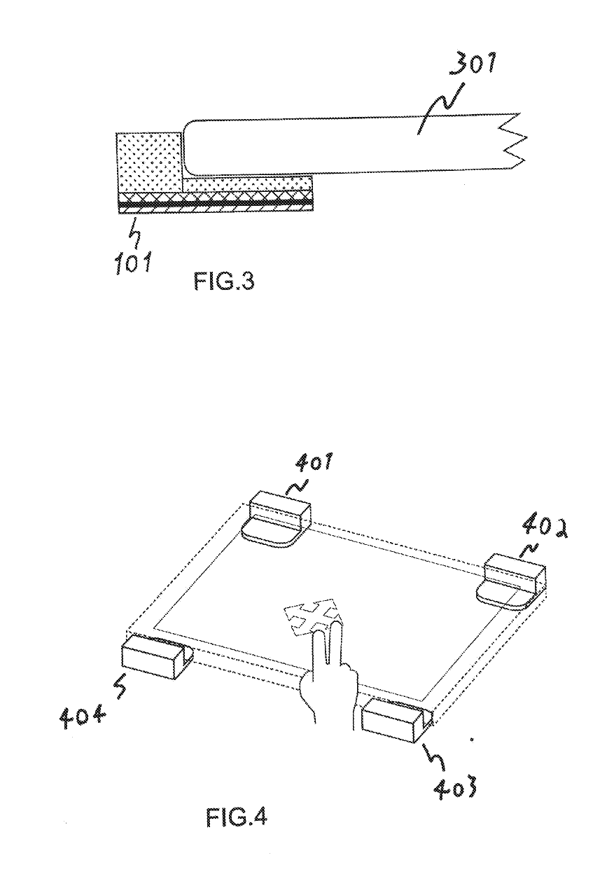

In use, in a typical configuration, a group of four stabilising blocks are used. They are applied by a user to a surface (such as a lapboard surface) so a block orientated for maximal contact with the tablet, is located at each of the two ends of the tablet's front edge (i.e. an edge closest the user), and likewise at each of the two ends of the tablet's rear edge (i.e. an edge furthest from the user). FIG. 3 provides a schematic diagram of an edge portion of a tablet 301 positioned for maximal contact with a stabilising block 101. FIG. 4 provides a schematic diagram depicting the typical configuration in which four stabilising blocks 401, 402, 403, 404 are used as described above. The example position of the tablet is indicated by broken lines.

Advantageously, in use, the weight of the tablet placed on the block (for example as depicted in FIG. 3) exerts a pressure that reinforces the adhesion of the block to the surface, thereby assisting in maintaining stability of the block and the tablet.

Further, in use the second stabilising part of each block obstructs the tablet moving forward and backward, even if the table surface tilts towards or away from a user.

In use, each block's tablet engaging surface acts to prevent the tablet moving left-right (relative to a user), even if the table surface tilts sideways (e.g. tilts to the left or right relative to the user). The angle of sideways tilt at which the tablet remains stationary can be substantial if the blocks are positioned so that the tablet stabilising parts of each block are snug and in contact against the edges of the tablet.

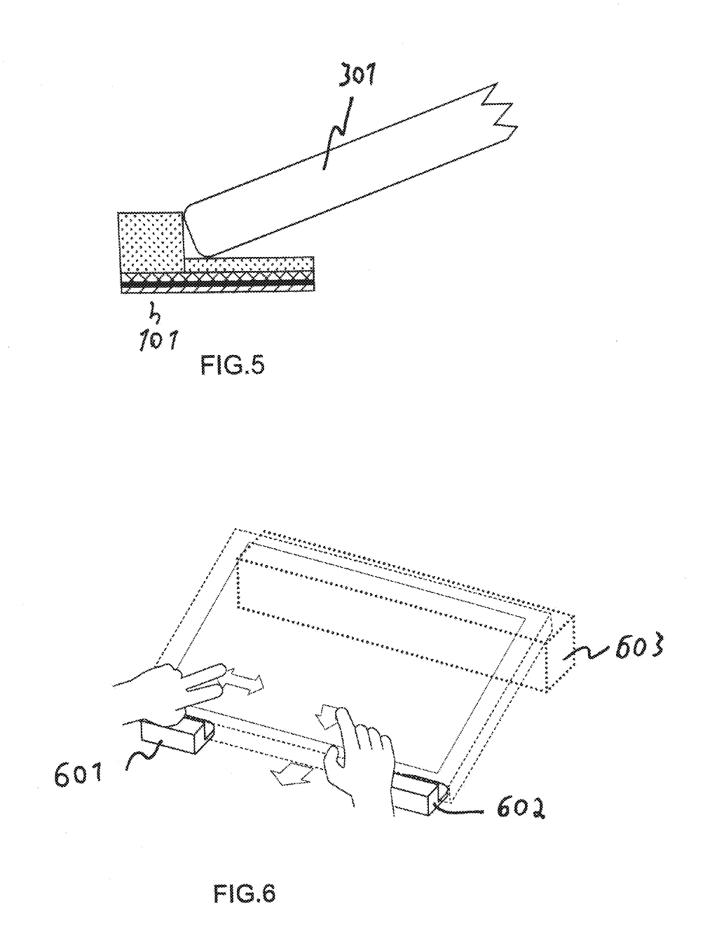

In alternative configurations, fewer stabilising blocks can be used as depicted schematically in FIGS. 5 and 6. FIG. 6 provides a schematic diagram depicting a configuration in which only two stabilising blocks 601, 602 are used on an edge of the tablet closest to a user. The far edge of the tablet is elevated by an elevating block 603. As depicted in FIG. 5, in use, at the front edge of the tablet, the second stabilising part stops the tablet moving or slipping down forward if the tablet's rear edge is supported at a raised position.

As will be appreciated with reference to FIG. 6, in certain configurations, a single stabilising block could be used, for example when used for narrow touch-devices in portrait orientation, and positioned centrally supporting an edge of the tablet nearest a user.

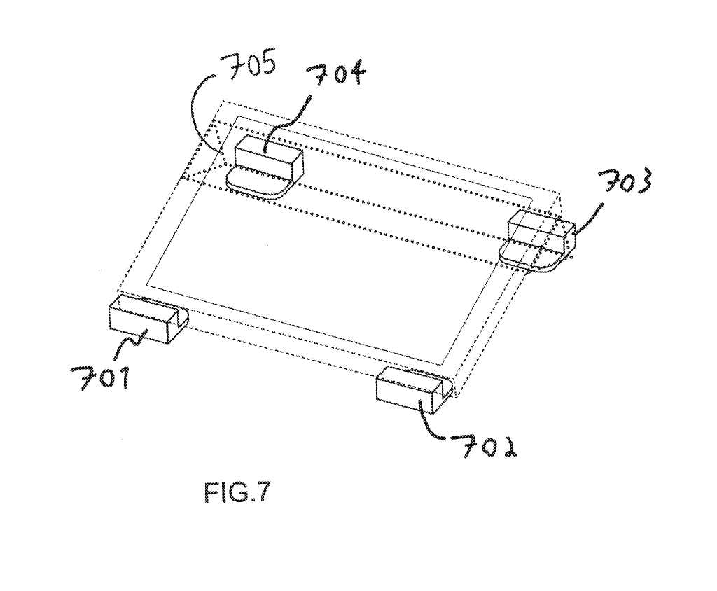

FIG. 7 depicts a configuration in which four stabilising blocks are deployed, two stabilising blocks 701, 702 are deployed at an edge of the tablet closest to the user. Two further stabilising blocks 703, 704 are positioned towards the opposite edge of the tablet furthest from the user and engage with a tablet elevating support 705, for example a tablet elevating support integral with the tablet or its cover.

Advantageously, the fact that the stabilising blocks are provided with an adhesive layer means that deployed stabilising blocks will remain in place if the surface on which they have been deployed is, for example, stored vertically.

Advantageously, if the adhesive layer of each block is non-permanent pressure sensitive adhesive, the blocks can be removed from a surface and then re-deployed in a different configuration.

In certain embodiments, the top surface of the second stabilising part of the block may incorporate additional features, for example a shaped groove for holding a cable, stylus or similar article. In certain embodiments, the second stabilising part may be shaped for branding or ornamental purposes.

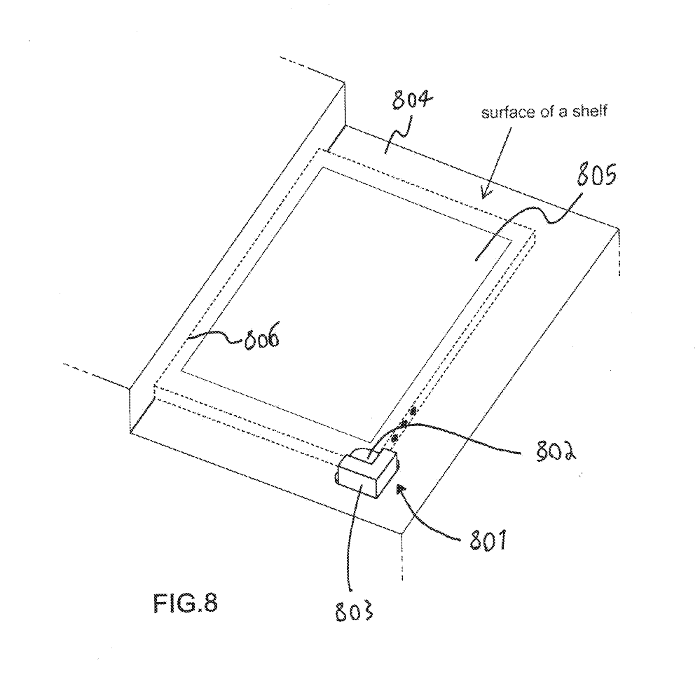

In the embodiments described above, the second stabilising part of the stabilising block that forms the tablet stop is of substantially rectangular block configuration. In certain embodiments, the second stabilising part may be substantially L-shaped, such that the stabilising block fits a corner of a tablet. FIG. 8 provides a schematic diagram of such an embodiment.

FIG. 8 depicts a stabilising block 801 in accordance with certain embodiments of the invention in which the second tablet stabilising part 803 has an L shaped configuration. As can be seen in FIG. 8, other components of the stabilising block 801, for example the first tablet stabilising part 802 have a substantially square shape.

FIG. 8 depicts the stabilising block 801 being used in conjunction with a shelf 804 against which one side 806 of a tablet 805 abuts. As will be appreciated, in this configuration, the single stabilising block with an L-shaped second tablet stabilising part 803 can be used to stabilise the tablet 805 if the shelf 804 is tipped in a direction towards the stabilising block 801.

In accordance with certain embodiments, a kit of parts is provided comprising a plurality of stabilising blocks as described above. In certain embodiments, the kit of parts comprises four stabilising blocks. In certain such embodiments, the blocks are mounted, either individually or together, on a piece of polypropylene card. The polypropylene card is used as backing that preserves the medium tack underside of the blocks when they are no longer required on a surface. In certain embodiments, such a kit may be provided with a spare medium-tack cloth to be applied when a block's underside has worn out much of its adhesive tack.

Attention is directed to all papers and documents which are filed concurrently with or previous to this specification in connection with this application and which are open to public inspection with this specification, and the contents of all such papers and documents are incorporated herein by reference. All of the features disclosed in this specification (including any accompanying claims, abstract and drawings), and/or all of the steps of any method or process so disclosed, may be combined in any combination, except combinations where at least some of such features and/or steps are mutually exclusive. Each feature disclosed in this specification (including any accompanying claims, abstract and drawings) may be replaced by alternative features serving the same, equivalent or similar purpose, unless expressly stated otherwise.

Thus, unless expressly stated otherwise, each feature disclosed is one example only of a generic series of equivalent or similar features. The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A stabilising block for holding an electronic tablet in place on a surface, said block comprising a fixing layer for fixing the block to the surface, a first stabilising part, and a second stabilising part, wherein,
said first stabilising part provides a tablet engaging surface and said second stabilising part projects above said first stabilising part forming a tablet stop.

2. A stabilising block according to claim 1, wherein the first stabilising part is substantially planar.

3. A stabilising block according to claim 1, wherein the fixing layer is an adhesive layer.

4. A stabilising block according to claim 3, wherein the adhesive layer is a pressure sensitive adhesive layer.

5. A stabilising block according to claim 4, wherein the pressure sensitive adhesive layer is a pressure sensitive medium-tack adhesive cloth.

6. A stabilising block according to claim 3, wherein the adhesive layer is a semi-permanent, reusable adhesive layer.

7. A stabilising block according to claim 3, wherein the adhesive layer is disposed on a base of the stabilising block adjacent a flexible core layer.

8. A stabilising block according to 7, wherein the flexible core layer comprises a plastic sheet.

9. A stabilising block according to claim 1, wherein the second stabilising part comprises high friction cell foam.

10. A stabilising block according to claim 9, wherein the first stabilising part comprises high friction cell foam.

11. A stabilising block according to claim 1, wherein the block is formed by adhering together the first stabilising part and the stabilising second stabilising part.

12. A stabilising block according to claim 1, wherein the first stabilising part and second stabilising part are formed from a single shaped piece.

13. A stabilising block according to claim 12, wherein the first stabilising part and second stabilising part are formed by carving or cast moulding.

14. A stabilising block according to claim 1, wherein a cross-section of the second stabilising part is substantially L-shaped.

15. A stabilising block according to claim 1, wherein a peripheral edge of the first stabilising part comprises at least two rounded corners.

16. A kit of parts comprising a plurality of stabilising blocks according to claim 1.

17. A kit of parts according to claim 16, comprising at least four stabilising blocks.
